(19) United States
(12) Patent Application Publication
(10) Pub. No.: US 2024/0322482 A1
(43) Pub. Date: Sep. 26, 2024

(54) ELECTRONIC DEVICE AND CORRESPONDING PRODUCT SERIES

(71) Applicant: AUMA RIESTER GMBH & CO. KG, MÜLLHEIM (DE)

(72) Inventor: Rüdiger STENZEL, Hilchenbach (DE)

(73) Assignee: AUMA RIESTER GMBH & CO. KG, MÜLLHEIM (DE)

(21) Appl. No.: 18/276,775

(22) PCT Filed: Sep. 21, 2022
(86) PCT No.: PCT/EP2022/076226

§ 371 Date: Aug. 10, 2023

(30) Foreign Application Priority Data
Dec. 3, 2021 (DE) 10 2021 131 953.6

(51) Int. Cl. H01R 13/52; H01R 13/74

(52) U.S. Cl. CPC H01R 13/5221; H01R 13/5202; H01R 13/748

(57) ABSTRACT

It is proposed in an electronic apparatus having a housing which has an opening into which a plug part of an electrical plug connection is inserted, wherein the opening is able to be closed with a pot-shaped cover that receives a mating plug part of the electrical plug connection, wherein the plug part on the rear side thereof is potted, that the housing is connected to the cover in a sealing manner.

### CROSS REFERENCE TO RELATED APPLICATIONS

This application is a national stage of International Application No. PCT/EP2022/076226 filed on Sep. 21, 2022, which claims priority to German Patent Application No. 10 2021 131 953.6 filed Dec. 3, 2021, all of which is hereby incorporated by reference in its entirety.

### BACKGROUND

The invention relates to an electronic apparatus having a housing which has an opening in which is inserted a plug part of an electrical plug connection, wherein the opening is able to be closed with a pot-shaped cover that receives a mating plug part of the electrical plug connection, wherein the plug part on the rear side thereof is potted. An electronic apparatus of this type is used in practice in many applications.

The invention furthermore relates to a type series having two variants. A type series of this type is known.

Apparatuses of this type can be implemented, for example, as actuating drives or as a control installation for an actuating drive, wherein electrical contacting is routed by way of a cable into the cover and on the latter is connected to a mating plug part for the plug part so that the cover establishes the plug connection or the electric contact with the mating plug part and the plug part.

### BRIEF DESCRIPTION

The invention is based on the object of improving the operating properties and the interconnection of electronic apparatuses. The invention is furthermore based on the object of providing an inherently tight assembly which acts in a sealing manner in relation to external influences such as water or dust and provides positive protection against corrosion.

In order for the set object to be achieved, the invention proposes the features of claim 1. In particular, in an electronic apparatus of the type described at the outset it is thus proposed according to the invention that, for achieving the object mentioned, the housing is connected to the cover in a sealing manner. In this way, an inherently tight assembly can be provided.

Advantageous design embodiments of the invention which can be implemented individually or in combination with the features of other design embodiments, optionally conjointly with the features according to claim 1, will be described hereunder.

It is to be pointed out that the features set forth individually in the dependent claims may be combined in any technologically expedient manner and define further design embodiments of the invention. Moreover, the features stated in the claims will be described and explained in more detail in the description, wherein further preferred design embodiments of the invention are illustrated.

In one advantageous design embodiment it can be provided that the plug part and the mating plug part are releasably connected. In this way, the electronic apparatus can be assembled or mounted in a simple and time-saving manner.

In one advantageous design embodiment it can be provided that the cover has an annular seal which has a larger diameter than the mating plug part. In this way, sealing in relation to external influences such as wind, water or dust can be provided. The annular seal is preferably configured as an annular cover seal.

In one advantageous design embodiment it can be provided that the annular seal has a larger diameter than the plug part. In this way, sealing in relation to external influences such as wind, water or dust can be provided.

In one advantageous design embodiment it can be provided that the plug part on the inside is connected to the housing, preferably directly. Alternatively or additionally, the plug part can be connected to the cover so as to be spaced apart, in an insertion direction of the plug part, from a sealing face of the housing. An assembly which can easily be mounted can thus be provided.

The cover preferably has a preferably circular opening through which cables and an electrical plug connection can be routed. The cables and the electrical plug connection can supply power to an actuating drive. Alternatively or additionally, the cable can transmit setting parameters such as position, speed or torque to the actuating drive.

In one advantageous design embodiment it can be provided that the plug part is connected to a potted part in a form-fitting manner. Alternatively or additionally, the plug part can be connected to the potted part in a force-fitting manner. In this way, a space-saving assembly which is easy to mount can be provided.

In one advantageous design embodiment it can be provided that the potted part is connected to a mating potted part. An assembly with a good sealing action can thus be provided.

The potted part is preferably connected to the mating potted part in a materially integral manner, for example by way of an adhesively bonded connection.

In one advantageous design embodiment it can be provided that the mating potted part possesses a cable conduit which is preferably disposed so as to be centric to the housing. Power for the actuating drive can be provided, or parameters for the actuating drive can be set, in this way.

In one advantageous design embodiment it can be provided that a potting socket is configured. The potting socket is preferably composed of a plastics material or a metal. The casting compound can be filled efficiently and in a space-saving manner in this way.

In one advantageous design embodiment it can be provided that the potting socket contacts the mating potted part, the potted part and additionally or alternatively the plug part. A space-saving assembly can be achieved in this way.

In one advantageous design embodiment it can be provided that the potting socket is held on the plug part by a casting compound. The casting compound encompasses the potted part and additionally or alternatively the mating potted part. In this way, an inherently tight assembly can be made available.

In one advantageous design embodiment it can be provided that the diameter of the potting socket is smaller than the diameter of the plug part. A space-saving assembly can be provided in this way.

In one advantageous design embodiment it can be provided that the plug part is connected to the housing by means of fastening elements, in particular threaded connections. A simple and cost-effective connection can be achieved in this way.

In one advantageous design embodiment it can be provided that an annular seal, preferably an annular potting socket seal, is configured between the potting socket and the housing. In this way, sealing between individual parts within the housing can be achieved.

In one advantageous design embodiment it can be provided that the diameter of the annular seal, preferably of the annular potting socket seal, is smaller than a maximum diameter of the potting socket. An assembly with an exact fit can be provided in this way.

In one advantageous design embodiment it can be provided that the cable conduit leads through a hole in the potting socket. The hole is preferably circular. A space-saving assembly with an exact fit can be provided in this way.

In one advantageous design embodiment it can be provided that a fastening space is configured between the plug part and the mating plug part. A mechanically stable assembly can be achieved in this way.

In one advantageous design embodiment it can be provided that the potting socket at one end protrudes directly into the fastening space. A mechanically stable assembly can be achieved in this way.

In one advantageous design embodiment it can be provided that fastening elements protrude into the fastening space. The fastening elements are preferably screws. A mechanically stable connection can be provided in this way.

The fastening elements preferably connect the mating plug part to the cover, or the plug part to the housing, respectively. As a result of the use of fastening elements, the assembly can be easily mounted in the cover and in the housing and dismantled therefrom.

In one advantageous design embodiment it can be provided that the mating plug part is connected to the cover by means of fastening elements. An assembly which is easy to mount can be provided in this way.

In one advantageous design embodiment it can be provided that the plug part is connected to the housing by means of fastening elements. An assembly which is easy to mount can be provided in this way.

In one advantageous design embodiment it can be provided that the plug part possesses openings into which pins are insertable. The pins are electrically configured and comprise a pin body and electric lines. The pins are installed in the openings in a sealing manner such that no moisture can penetrate via said pins. A control unit for the actuating drive is provided in this way.

In one advantageous design embodiment it can be provided that the potted part is connected to the potting socket in a materially integral manner, and alternatively or additionally in a form-fitting manner. A compact assembly with an exact fit can be provided in this way.

The materially integral connection can be achieved by an adhesively bonded connection.

Provided according to the invention for achieving the object mentioned are the features of the coordinate claim directed toward a type series. In a type series of the type mentioned at the outset it is thus proposed according to the invention for achieving the mentioned object that in a first variant an electronic apparatus is configured according to the previously mentioned features, and in a second variant in which a plug part is designed without potting, wherein the first variant and the second variant have at least identical covers and housings. A tight assembly can be provided in this way.

In one advantageous design embodiment of the type series it can be provided that the first variant and the second variant have identical plug parts, and additionally or alternatively identical mating plug parts, and additionally or alternatively the second variant is without a potting socket. In this way, alternatives in terms of construction can be provided.

The invention will now be described by means of an exemplary embodiment but is not limited to this exemplary embodiment. Further exemplary embodiments are derived by combining the features of individual or several claims with one another and/or with individual or several features of the exemplary embodiment.

### BRIEF DESCRIPTION OF THE DRAWINGS

FIG. 1 shows an electronic apparatus without casting compound in a sectional illustration; and

FIG. 2 shows an electronic apparatus with casting compound in a sectional illustration.

### DETAILED DESCRIPTION

In the description hereunder of various exemplary embodiments of the invention, functionally equivalent elements are provided with the same reference numerals even in the case of deviating design or shape.

For improved clarity, not all reference signs are placed in the figures while the elements may very well be present in the figures. However, identical reference signs refer to components and functional units which are identical in terms of function and/or construction.

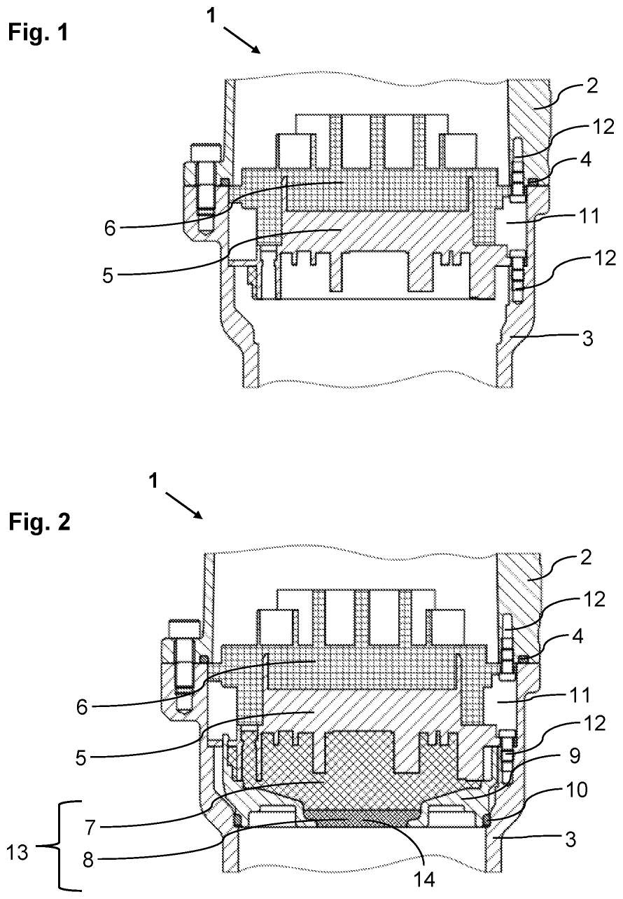

FIG. 1 shows an electronic apparatus 1 without a casting compound 13 in a sectional illustration.

The electronic apparatus 1 comprises a pot-shaped cover 2 and a housing 3. The two parts are connected to one another by way of fastening elements configured as threaded connections, wherein an annular seal 4 seals the face between the cover 2 and the housing 3.

The electronic apparatus furthermore comprises a plug part 5 and a mating plug part 6, wherein the two parts are connected to one another in a form-fitting and/or force-fitting manner.

The mating plug part 6 is connected to the cover 2 by a fastening element. The plug part 5 is connected to the housing 3 by a fastening element.

The plug part 5 has openings (not illustrated) into which electrical pins are insertable. The electrical pins (not illustrated) in a manner known per se have a pin body and electric lines. The electric lines direct power to the actuating drive, or comprise a data transfer by way of which parameters for the actuating drive can be set. Potential parameters for the actuating drive may be, for example, a position, a closing speed, or a torque.

FIG. 2 shows an electronic apparatus 1 having a casting compound 13 in a sectional illustration.

The electronic apparatus 1 comprises a pot-shaped cover 2 and a housing 3. The two parts are connected to one another by way of fastening elements configured as threaded connections, wherein an annular seal 4 seals the face between the cover 2 and the housing 3.

The electronic apparatus furthermore comprises a plug part 5 and a mating plug part 6. The two parts connected to one another in a form-fitting and/or force-fitting manner.

The plug part possesses openings (not illustrated) which can receive electrical pins (not illustrated). The electrical pins comprise a pin body and electric lines running through the latter.

The mating plug part 6 is connected to the cover 2 by means of a fastening elements. The pin part 5 is connected to the housing 3 by means of a fastening element 12.

A fastening space 11 is configured between the plug part 5 and the mating plug part 6.

The electronic apparatus 1 furthermore comprises a potted part 7 and a mating potted part 8 and a potting socket 9. The potting socket 9 contacts the plug part 5, the potted part 7 and the mating potted part 8. An annular seal 10 which protects the interior of the housing in relation to invading moisture or contamination by dust is configured between the potting socket 9 and the housing 3.

The potting socket 9 has a preferably circular hole in which a cable conduit 14 is configured so as to be centric to the housing 3.

The plug part 5 and the mating plug part 6 are releasably connected to one another.

The cover 2 has an annular seal 4 which has a larger diameter than the mating plug part 6 and than the plug part 5.

The plug part 5 is connected to the potted part 7 in a form-fitting manner, and additionally or alternatively in a force-fitting manner.

The potted part 7 is connected to the mating potted part 8.

The mating potted part 8 is disposed in a hole of the potting socket 9.

The potting socket 9 contacts the potted part 7 and/or the plug part 5. The potting socket 9 is held on the plug part 5 by a casting compound 13. The casting compound 13 is configured as a potted part 7 and as a mating potted part 8. The diameter of the potting socket 9 is smaller than the diameter of the plug part 5.

The plug part 5 is connected to the housing 3 by means of fastening elements 12. These fastening elements 12 are preferably screws.

An annular seal 10 is configured between the potting socket 9 and the housing 3. The diameter of the annular seal 10 is smaller than the maximum diameter of the potting socket 9. A cable conduit 14 leads through a hole in the potting socket 9.

A fastening space 11 is configured between the plug part 5 and the mating plug part 6. The potting socket 9 at one end protrudes directly into the fastening space 11. Fastening elements 12, in particular screws, likewise protrude into the fastening space 11.

The mating plug part 6 is connected to the cover 2 by means of fastening elements 12. The plug part 5 is connected to the housing 3 by means of fastening elements 12.

The plug part 5 possesses openings (not illustrated) into which electrical pins are insertable.

The potted part 7 is connected to the potting socket 9 in a materially integral and/or form-fitting manner.

It is proposed in an electronic apparatus having a housing which has an opening into which a plug part of an electrical plug connection is inserted, wherein the opening is able to be closed with a pot-shaped cover that receives a mating plug part of the electrical plug connection, wherein the plug part on the rear side thereof is potted, that the housing is connected to the cover in a sealing manner.

1. An electronic apparatus having a housing which has an opening in which is inserted a plug part of an electrical plug connection, wherein the opening is able to be closed with a pot-shaped cover that receives a mating plug part of the electrical plug connection, wherein the plug part on the rear side thereof is potted, wherein the housing is connected to the cover in a sealing manner.

2. The electronic apparatus as claimed in claim 1, characterized in that the plug part and the mating plug part are releasably connected.

3. The electronic apparatus as claimed in claim 1 wherein the cover has an annular seal, in particular an annular cover seal, which has a larger diameter than the mating plug part.

4. The electronic apparatus as claimed in claim 1 wherein the annular seal, in particular the annular cover seal, has a larger diameter than the plug part.

5. The electronic apparatus as claimed in claim 1 wherein the plug part on the inside is preferably directly connected to the housing and/or is connected to the cover so as to be spaced apart, in an insertion direction of the plug part, from a sealing face of the housing.

6. The electronic apparatus as claimed in claim 1 wherein the plug part is connected to a potted part in a form-fitting and/or force-fitting manner.

7. The electronic apparatus as claimed in claim 1 wherein the potted part is connected to a mating potted part.

8. The electronic apparatus as claimed in claim 1 wherein the mating potted part possesses a cable conduit which is preferably disposed so as to be centric to the housing.

9. The electronic apparatus as claimed in claim 1 wherein a potting socket is configured.

10. The electronic apparatus as claimed in claim 1 wherein the potting socket contacts the mating potted part, the potted part and/or the plug part.

11. The electronic apparatus as claimed in claim 1 wherein the potting socket is held on the plug part by a casting compound.

12. The electronic apparatus as claimed in claim 1 wherein the diameter of the potting socket is smaller than the diameter of the plug part.

13. The electronic apparatus as claimed in claim 1 wherein the plug part is connected to the housing by means of fastening elements.

14. The electronic apparatus as claimed in claim 1 wherein an annular potting socket seal is configured between the potting socket and the housing.

15. The electronic apparatus as claimed in claim 1 wherein the diameter of the annular potting socket seal is smaller than a maximum diameter of the potting socket.

16. The electronic apparatus as claimed in claim 1 wherein the cable conduit leads through a hole in the potting socket.

17. The electronic apparatus as claimed in claim 1 wherein a fastening space is configured between the plug part and the mating plug part.

18. The electronic apparatus as claimed in claim 1 wherein the potting socket at one end protrudes directly into the fastening space.

19. The electronic apparatus as claimed in claim 1 wherein fastening elements, in particular screws, protrude into the fastening space.

20. The electronic apparatus as claimed in claim 1 wherein the mating plug part is connected to the cover by means of fastening elements, in particular screws.

21. The electronic apparatus as claimed in claim 1 wherein the plug part is connected to the housing by means of fastening elements.

22. The electronic apparatus as claimed in claim 1 wherein the plug part possesses openings into which pins are insertable.

23. The electronic apparatus as claimed in claim 1 wherein the potted part is connected to the potting socket in a materially integral and/or form-fitting manner.

24. A type series of an electronic apparatus, having a first variant in which the electronic apparatus is designed according to claim 1, and a second variant in which a plug part is designed without potting, characterized in that the first variant and the second variant have at least identical covers and housings.

25. The type series as claimed in claim 24, characterized in that the first variant and the second variant have identical plug parts and/or identical mating plug parts, and/or in that the second variant is without a potting socket.
